(19) United States
(12) Patent Application Publication
(10) Pub. No.: US 2009/0261346 A1
(43) Pub. Date: Oct. 22, 2009

(54) Integrating CMOS and Optical Devices on a Same Chip

(76) Inventors: Ding-Yuan Chen, Taichung (TW); Chen-Hua Yu, Hsin-Chu (TW)

Correspondence Address: SLATER & MATSIL, L.L.P., 17950 PRESTON ROAD, SUITE 1000, DALLAS, TX, 75252, US

(21) Appl. No.: 12/127,569

(22) Filed: May 27, 2008

Related U.S. Application Data
(60) Provisional application No. 61/045,513, filed on Apr. 16, 2008.

(51) Int. Cl. H01L 27/15; H01L 33/00

(52) U.S. Cl. 257/76; 257/E27.12; 257/E33.025

(57) ABSTRACT

An integrated circuit structure includes a semiconductor substrate having a first surface region and a second surface region, wherein the first surface region and the second surface region have different surface orientations; a semiconductor device formed at a surface of the first surface region; and a group-III nitride layer over the second surface region, wherein the group-III nitride layer does not extend over the first surface region.

This application claims the benefit of the following provisionally filed U.S. Patent Application Ser. No. 61/045,513, filed Apr. 16, 2008, entitled “Integrating CMOS and Optical Devices on a Same Chip” which application is hereby incorporated herein by reference.

### TECHNICAL FIELD

This invention relates generally to integrated circuit manufacturing processes, and more particularly to the structures having complementary metal-oxide-semiconductor (CMOS) devices and optical devices integrated on a same chip, and methods for forming the same.

### BACKGROUND

In recent years, optical devices such as light emitting diodes (LEDs), laser diodes, and UV photo-detectors have increasingly been used. The substrates for forming these devices were also studied. Group-III nitride compounds, such as gallium nitride (GaN) and its related alloys, have been known to be well suitable for the formation of the optical devices. The large bandgap and high electron saturation velocity of the group-III nitride compounds also make them excellent candidates for applications in high temperature and high-speed power electronics.

However, due to the high equilibrium pressure of nitrogen at typical growth temperatures, it is extremely difficult to obtain GaN bulk crystals. Owing to the trigonal symmetry of silicon (111) substrates, GaN is commonly deposited epitaxially on silicon (111) substrates. However, silicon (111) substrates are rarely used for conventional CMOS applications, and hence have a relatively high price and less availability. In addition, silicon (111) substrates suffer from interface traps. As a result, the use of silicon (111) substrates prevents the integration of CMOS devices and optical devices on a same semiconductor chip.

CMOS devices are not suitable for being formed on silicon (111) substrates. Therefore, CMOS devices have to be formed on a first semiconductor chip, for example, with a silicon (100) substrate. The optical devices are formed on a second semiconductor chip, for example, a silicon (111) chip. The first and the second semiconductor chips are then packaged together.

Forming CMOS devices and optical devices on separate semiconductor chips incurs high packaging cost. In addition, the wiring and bonding between the optical chip and the CMOS chip result in greater parasitic capacitances and resistances, which adversely affect the performance of the resulting packages. New methods for forming integrated circuits combining CMOS devices and optical devices on a same chip are thus needed.

### SUMMARY OF THE INVENTION

In accordance with one aspect of the present invention, an integrated circuit structure includes a semiconductor substrate having a first surface region and a second surface region, wherein the first surface region and the second surface region have different surface orientations; a semiconductor device formed at a surface of the first surface region; and a group-III nitride layer over the second surface region, wherein the group-III nitride layer does not extend over the first surface region.

In accordance with another aspect of the present invention, an integrated circuit structure includes a semiconductor chip. The semiconductor chip includes a silicon substrate having a (100) surface orientation; a first surface region on the silicon substrate, wherein the first surface region comprises crystalline silicon having a (100) surface orientation; a second surface region on the silicon substrate, wherein the second surface region comprises crystalline silicon having a (111) surface orientation; a complementary metal-oxide-semiconductor (CMOS) device at a top surface of the first surface region; and an optical device over the second surface region.

In accordance with yet another aspect of the present invention, an integrated circuit structure includes a silicon substrate; a first surface region on the silicon substrate, wherein the first surface region includes crystalline silicon having a (100) surface orientation; a second surface region of the silicon substrate, wherein the second surface region includes crystalline silicon having a (111) surface orientation; a CMOS circuit at a top surface of the first surface region; a gallium nitride (GaN) layer over the second surface region; and an optical device over the GaN layer.

In accordance with yet another aspect of the present invention, a method of forming an integrated circuit structure includes providing a silicon substrate having a first surface orientation selected from the group selected from the group consisting essentially of a (100) surface orientation and a (110) surface orientation; providing a silicon layer having a (111) surface orientation bonded on the silicon substrate; and converting a surface orientation of a first region of the silicon layer to a same surface orientation as the silicon substrate, wherein a second region of the silicon layer remains to have the (111) surface orientation.

In accordance with yet another aspect of the present invention, a method of forming an integrated circuit structure includes providing a silicon substrate having a (100) surface orientation; providing a silicon layer having a (111) surface orientation bonded on the silicon substrate; implanting a first region of the silicon layer to form an amorphous region, wherein the amorphous region extends into the silicon substrate, and wherein a second region of the silicon layer is not implanted; re-crystallizing the amorphous region to convert the amorphous region to a third region having the (100) surface orientation; forming a CMOS device at a surface of the third region; and forming a light-emitting diode over the second region of the silicon layer.

By using the embodiments of the present invention, CMOS devices and optical devices may be formed on a same semiconductor chip, with the performance of the CMOS devices and optical devices optimized.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1 through 4 are cross-sectional views of intermediate stages in the manufacturing of an embodiment of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

A semiconductor chip/wafer having both complementary metal-oxide-semiconductor (CMOS) devices and optical devices integrated thereon, and the methods for forming the same, are provided. The intermediate stages of manufacturing a preferred embodiment of the present invention are illustrated. Throughout the various views and illustrative embodiments of the present invention, like reference numbers are used to designate like elements.

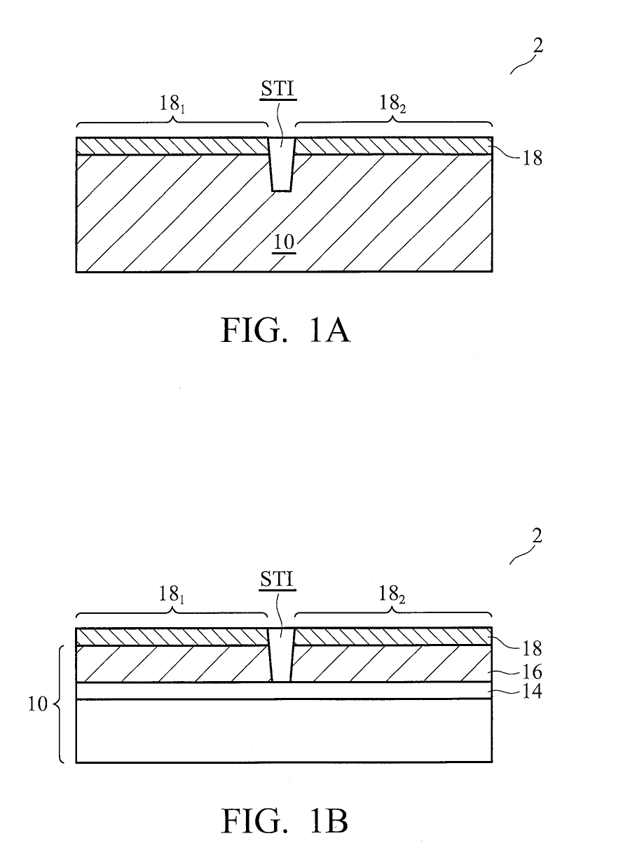

Referring to FIGS. 1A and 1B, semiconductor chip 2 is provided. Semiconductor chip 2 may be a portion of a semiconductor wafer, and includes semiconductor substrate 10. Semiconductor substrate 10 is preferably a silicon substrate. In an embodiment, semiconductor substrate 10 has a (100) surface orientation. In other embodiments, semiconductor substrate 10 has a (110) surface orientation. Silicon substrate 10 may be a bulk substrate, as is shown in FIG. 1A, or may be a silicon-on-insulator (SOI) substrate having buried oxide 14 between silicon layers, as is shown in FIG. 1B. In the structure shown in FIG. 1B, the upper silicon layer 16 preferably has a (100) surface orientation or a (110) surface orientation.

Semiconductor layer 18 is bonded on semiconductor substrate 10. Semiconductor layer 18 and semiconductor substrate 10 have different surface orientations. In an embodiment, semiconductor layer 18 has a (111) surface orientation, and hence is referred to as silicon (111) layer 18 throughout the description, although its surface may have other surface orientations. Silicon (111) layer 18 includes region 18₁ and region 18₂, which may be separated by isolation structures, for example, a shallow trench isolation (STI) region. Silicon (111) layer 18 may comprise carbon, for example, to a concentration of about one atomic percent to about two atomic percent.

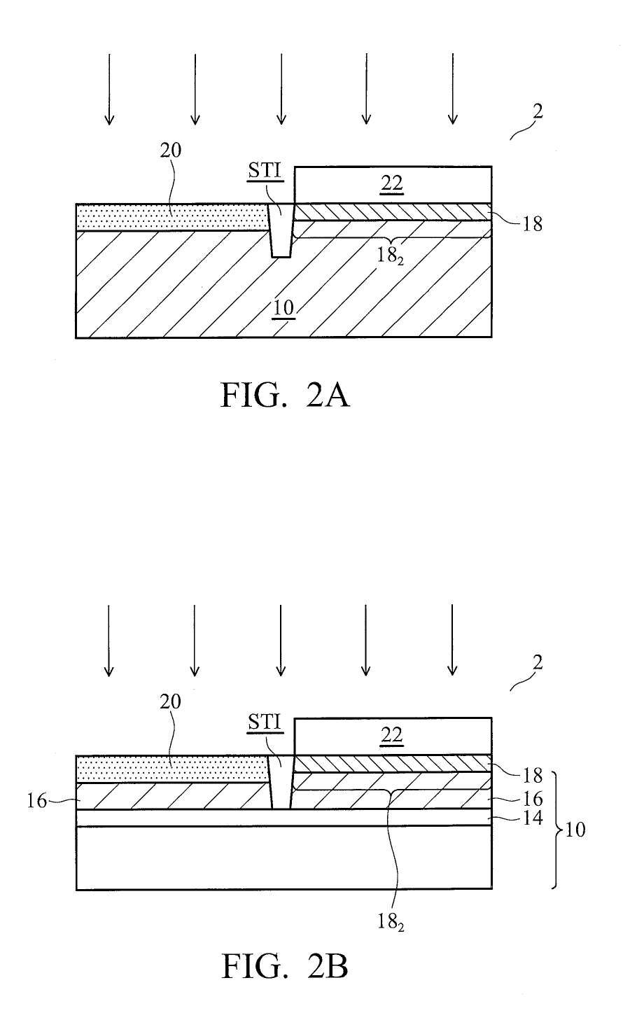

Referring to FIGS. 2A and 2B, an amorphization is performed to amorphize region 18₁ of silicon (111) layer 18, forming amorphous region 20. In an exemplary embodiment, the amorphization is performed by implanting ions such as argon, germanium, or the like, into region 18₁. Amorphous region 20 preferably extends below silicon (111) layer 18 and into semiconductor substrate 10, and hence a surface layer of semiconductor substrate 10 is also amorphized. In the case semiconductor substrate 10 has an SOI structure, as shown in FIG. 2B, amorphous region 20 preferably extends into the upper silicon layer 16, but does not contact buried oxide 14. Region 18₂ of silicon (111) layer 18 is protected from the amorphization by mask 22, for example.

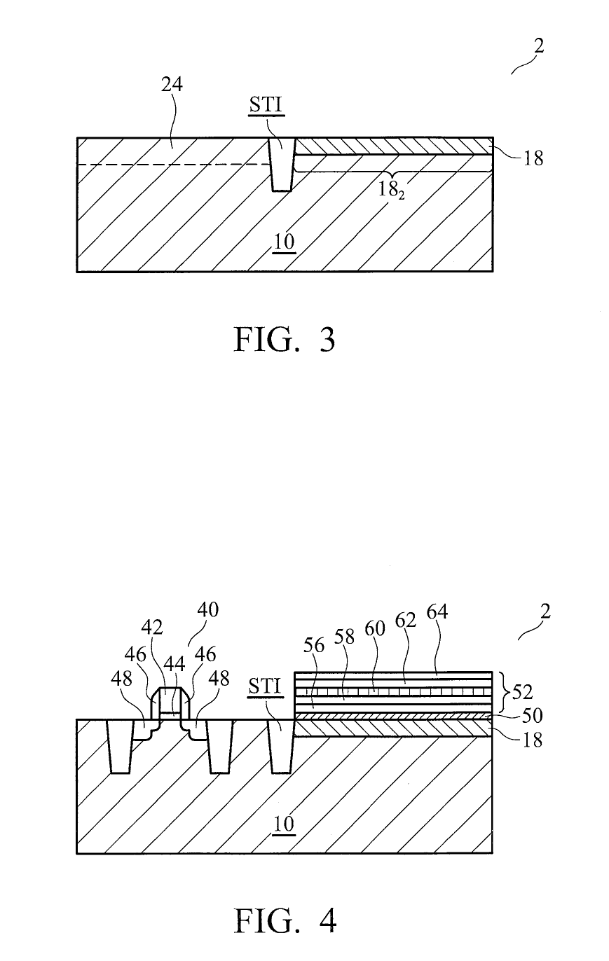

Referring to FIG. 3, a re-crystallization is performed to re-crystallize amorphous region 20, forming crystalline region 24. In an embodiment, the re-crystallization is performed using a solid phase epitaxy (SPE) anneal, in which semiconductor chip 2 is annealed for about 4 minutes to about 24 minutes at relatively low temperatures, for example, about 600° C. In other embodiments, high-temperature spike anneal is performed. In yet other embodiments, a laser anneal is performed to melt, and re-crystallize, the silicon in amorphous region 20. After the re-crystallization, the resulting crystalline region 24 will have a same surface orientation as that of semiconductor substrate 10. On the other hand, the surface orientation of region 18₂ is not changed by the anneal.

After the re-crystallization, semiconductor chip 2 includes two surface regions having different surface orientations. For example, surface region 24 may have a (100) or a (110) surface orientation, while region 18₂ of silicon layer 18 may have a (111) surface orientation. Different devices may thus be formed on surface regions 24 and 18₂.

FIG. 4 illustrates the formation of semiconductor device(s) 40 and optical devices on the structure shown in FIG. 3. An exemplary MOS device 40 is shown as being formed at the surface of surface region 24, wherein the MOS device 40 includes gate electrode 42, gate dielectric 44, gate spacers 46, and source/drain regions 48. Semiconductor device 40 may be formed at the surface of surface region 24, and may include CMOS devices (PMOS devices and NMOS devices), diodes, or the like. As is known in the art, CMOS devices prefer silicon (100) or silicon (110) substrates, and the performance of the CMOS devices formed on these silicon substrates are improved over the MOS devices formed on other substrates, for example, silicon (111) substrates. Semiconductor device 40 may also include desirable CMOS circuits such as electro-static discharge (ESD) circuits/devices, which may be used to protect the optical devices formed on the same semiconductor chip 2, as will be discussed in detail in subsequent paragraphs, and/or driver circuits, for example, for driving the optical devices formed on the same semiconductor chip 2.

Optical devices may be formed over region 18₂ of silicon (111) layer 18. In an exemplary embodiment, group-III nitride layer 50, for example, GaN or AlN layer 50, is formed on silicon (111) layer 18 by epitaxy. Optical devices such as light-emitting diodes (LED), laser diodes, and/or ultra-violet (UV) photo-detectors, and/or the like, may then be formed on group-III nitride layer 50. Other devices that prefer group-III nitride substrates, such as a high-power microwave high electron mobility transistor (HEMT), may also be formed over group-III nitride layer 50. FIG. 4 illustrates an exemplary LED 52. It is realized that LEDs may have many designs, and FIG. 4 only shows an exemplary version among the designs. In an embodiment, LED 52 includes an optional distributed bragg reflector (DBR) 56 for reflecting light, a n-GaN layer (GaN doped with an n-type impurity) 58, a multiple quantum well (MQW) 60, a p-GaN layer (GaN doped with a p-type impurity) 62, and a top electrode 64. Alternatively, layer 50 may be a buffer layer formed of, for example, TiN, ZnO, AlN, or combinations thereof MQW 60 may be formed of, for example, InGaN, and acts as an active layer for emitting light. The formations of layers 56, 58, 60, 62, and 64 are known in the art, and hence are not repeated herein. As is known in the art, silicon (111) layers are suitable for forming GaN layers due to their trigonal symmetry. The group-III nitride layer 50 formed on silicon (111) layer 18 thus has an excellent crystalline structure, and hence the performance of the resulting optical device 52 is improved.

In the embodiments of the present invention, CMOS devices and optical devices are integrated in a same semiconductor chip. There are several advantageous features. For example, some optical devices may need electro-static discharge (ESD) devices/circuits for discharging the static charges that may cause damage to the optical devices. The ESD devices/circuits may include CMOS devices or diode devices. By using the embodiments of the present invention, the ESD devices are built-in the semiconductor chip for forming the optical devices. Since the formation of CMOS devices or diodes and the optical devices are wafer-based, the manufacturing cost is lower than the cost for packaging CMOS devices and optical devices chip-by-chip. The parasitic capacitance and the parasitic resistances caused by the wiring between the CMOS device chips and the optical device chips are reduced. In addition, the performance for the CMOS devices and the optical devices may be improved since they are formed on the silicon substrate/layer having desirable surface orientations.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. An integrated circuit structure comprising:
a semiconductor substrate having a first surface region and a second surface region, wherein the first surface region and the second surface region have different surface orientations;
a semiconductor device formed at a surface of the first surface region; and
a group-III nitride layer over the second surface region, wherein the group-III nitride layer does not extend over the first surface region.

2. The integrated circuit structure of claim 1, wherein the semiconductor device comprises a CMOS device.

3. The integrated circuit structure of claim 2, wherein the CMOS device is an electro-static discharge (ESD) device.

4. The integrated circuit structure of claim 2, wherein the CMOS device is a driver circuit.

5. The integrated circuit structure of claim 1, wherein the semiconductor device comprises a diode.

6. The integrated circuit structure of claim 1, wherein the first surface region has a surface orientation selected from the group consisting essentially of a (100) surface orientation and a (110) surface orientation, and the second surface region has a (111) surface orientation.

7. The integrated circuit structure of claim 6, wherein the first surface region has the (100) surface orientation.

8. The integrated circuit structure of claim 1, wherein the group-III nitride layer comprises gallium nitride (GaN).

9. The integrated circuit structure of claim 1 further comprising a light-emitting diode over the group-III nitride layer.

10. The integrated circuit structure of claim 1 further comprising a high-power microwave high electron mobility transistor (HEMT) over the group-III nitride layer.

11. An integrated circuit structure comprising:
a semiconductor chip comprising:
a silicon substrate having a (100) surface orientation;
a first surface region on the silicon substrate, wherein the first surface region comprises crystalline silicon having a (100) surface orientation;
a second surface region on the silicon substrate, wherein the second surface region comprises crystalline silicon having a (111) surface orientation;
a complementary metal-oxide-semiconductor (CMOS) device at a top surface of the first surface region; and
an optical device over the second surface region.

12. The integrated circuit structure of claim 11, wherein top surfaces of the first and the second surface regions are substantially leveled.

13. The integrated circuit structure of claim 11 further comprising a gallium nitride (GaN) layer on the second surface region, and a light-emitting diode on the GaN layer.

14. The integrated circuit structure of claim 11, wherein the second surface region comprises silicon carbon.

15. An integrated circuit structure comprising:
a silicon substrate;
a first surface region on the silicon substrate, wherein the first surface region comprises crystalline silicon having a (100) surface orientation;
a second surface region of the silicon substrate, wherein the second surface region comprises crystalline silicon having a (111) surface orientation;
a complementary metal-oxide-semiconductor (CMOS) circuit at a top surface of the first surface region;
a gallium nitride (GaN) layer over the second surface region; and
an optical device over the GaN layer.

16. The integrated circuit structure of claim 15, wherein the optical device is a light-emitting diode.

17. The integrated circuit structure of claim 15, wherein the CMOS circuit is an electro-static discharge (ESD) circuit.

18. The integrated circuit structure of claim 15, wherein the second surface region comprises silicon carbon.
